(19) United States
(12) Patent Application Publication
(10) Pub. No.: US 2010/0291315 A1
(43) Pub. Date: Nov. 18, 2010

(54) Method of Producing Multilayer Structures Having Controlled Properties

(75) Inventors: Daniel Fruchart, Meylan (FR); David Jean Maurice Vempaire, Claix (FR); Jacques Henri Lucien Pelletier, Saint Martin D'here (FR); Salvatore Miraglia, Grenoble (FR)

Correspondence Address: HARNESS, DICKEY & PIERCE, P.L.C., P.O. BOX 828, BLOOMFIELD HILLS, MI, 48303, US

(73) Assignees: CENTRE NATIONAL DE LA RECHERCHE SCIENTIFIQUE (CNRS, Paris (FR); UNIVERSITE JOSEPH FOURIERGRENOBLE 1, St. Martin d'Here (FR)

(21) Appl. No.: 12/225,773

(22) PCT Filed: Mar. 29, 2007
(86) PCT No.: PCT/EP2007/053002

§ 371 Date: Jul. 14, 2010

(30) Foreign Application Priority Data
Mar. 30, 2006 (FR) 06/02787

(51) Int. Cl. C23C 14/28

(52) U.S. Cl. 427/523

(57) ABSTRACT

The invention relates to a method of manufacturing (100) a multilayer structure on a support, the said structure comprising n elemental active layers of material, n being an integer greater than or equal to two, the method comprising at least the following steps: a step of depositing (200) a first elemental active layer of material, a step of depositing (300) an nth elemental active layer of material, characterized in that the method includes a single step of implanting ionic species (600) on the n elemental active layers of material deposited, through a resist, which is appropriate for modifying respective properties of each of the n elemental active layers in order to obtain a multilayer structure having controlled properties.

### CROSS-REFERENCE TO RELATED APPLICATIONS

This is a National Phase Entry of PCT/EP 2007/053002, filed Mar. 29, 2007, which claims priority to French Application No. 0602787, filed Mar. 30, 2006. Both of these applications are incorporated by reference herein.

### BACKGROUND AND SUMMARY

The present invention relates to methods for manufacturing microstructures and nanomultilayer structures having controlled properties, and more precisely having controlled magnetic and/or electronic properties. These multilayer structures having controlled properties are applied non-exclusively to the areas of microcircuit and micro-sensor production, systems used for information storage, such as magnetic or electric memories or even to the areas of spin electronics, photonics or optoelectronics.

A multilayer structure having controlled properties is defined as a structure comprising several thin layers having intrinsic magnetic and/or electronic properties suitable for acquiring or modifying these properties by introduction of an external element to their crystalline network. To date, the manufacture of multilayer structures based on thin layer stacks each having controlled magnetic and/or electronic properties used to require layer-by-layer fabrication of these structures. This fabrication could be implemented variously.

Use of the magnetron pulverisation technique is accordingly already known for manufacturing magnetic multilayer structures. However, this technique for depositing thin layers proposes very slow speeds for depositing layers. Alternative depositing techniques are also known, such as laser ablation, cathodic pulverisation, chemical, gas or liquid depositing. However, the manufacture of micro or nanomultilayer structures having controlled properties using such techniques generally requires a series of often-complex operations if the aim is to proceed by successive depositing of the different layers having controlled properties on a substrate.

A known solution for reducing the complexity of these techniques is to deposit a first layer and locally modify the magnetic and/or electronic properties by implantation of ionic elements via a mask using a bundle of ions, said elements changing the chemical composition and/or the crystallographic structure of the material of the layer. This operation is repeated for each of the following layers forming the multilayer structure.

A multilayer structure having several layers of materials having properties modified locally according to a precise pattern is obtained. However, this type of manufacturing method comprises a highly significant number of manufacturing steps since, apart from the implantation step of ionic elements for each level of material layer to be deposited, a series of operations is provided comprising a depositing operation followed by operations of placement, insolation and development of a mask via which the elements will be implanted in each layer. Also, at each layer level a step for aligning the masks is provided, a step not easy to perform with precision.

Dielectric contacts or barriers can also be made between the different layers which involve adding intermediate production steps. The major drawback to such a method is multiplying the steps necessary for manufacturing multilayer structures having controlled properties, considerably encumbering the method. Also, such a method having the disadvantage of being extremely costly in terms of production operations is likewise costly in terms of financial costs and production time.

A first aim of the invention is to eliminate these disadvantages. In fact, an aim of the invention is to propose a manufacturing method for multilayer structures having controlled properties entailing a much smaller number of manufacturing steps. Another aim of the invention is to propose a manufacturing method for multilayer structures having controlled properties which is simple, rapid and economical. It is also desirable to propose a manufacturing method for multilayer structures having controlled properties enabling control of the nature and dose of elements implanted at each level of layer of material.

Another aim of the invention is to propose a manufacturing method for multilayer structures having controlled properties allowing easy automation and in-situ control in real time of the implantation of ionic elements at each level of material layer. Finally, another aim of the invention is to propose a manufacturing method for multilayer structures having controlled properties offering the possibility of developing novel materials and novel micro- and nano-structures of non-synthesisable thin films by conventional methods.

These aims are achieved within the scope of the present invention due to a manufacturing method for a multilayer structure on a support, said structure comprising n active elementary layers of material, n being a whole number greater than or equal to two, comprising at least the following steps:

a depositing step of a first active elementary layer of material,

a depositing step of an nth active elementary layer of material characterised in that it comprises a single step of implanting ionic species on the n active elementary layers of deposited material, via a reserve, specific to modifying respective properties of each of the n active elementary layers to obtain a multilayer structure having controlled properties.

Advantageously, a method according to the invention further comprises a depositing step of at least one layer of material, so-called intermediate layer, between two active elementary layers of material, which intermediate layer fulfils a function different to those of the active elementary layers, said step being performed prior to said implanting of species ionic on the n active elementary layers of material deposited such that said implantation of ionic species is likely to also modify specific properties of said intermediate layer.

### BRIEF DESCRIPTION OF THE DRAWINGS

The invention will be better comprehended and other advantages and characteristics will emerge from the following description given by way of non-limiting example and by means of the attached diagrams, in which:

FIG. 1 illustrates a succession of views of a multilayer structure illustrating a synoptic sketch of a manufacturing method of a multilayer structure according to the invention; and

FIG. 2 illustrates a view of a multilayer structure illustrating a variant of the multilayer structure of FIG. 1.

### DETAILED DESCRIPTION

A manufacturing method 100 for a multilayer structure having n active elementary layers of material, n being a whole number greater than or equal to two, will now be described. Advantageously, the manufacturing method 100 comprises at least one depositing step of a first active elementary layer of material followed by a depositing step of an nth active elementary layer of material and by a single step of implanting ionic species on the n active elementary layers of material deposited, via a reserve, specifically for modifying the respective properties of each of the n active elementary layers to obtain a multilayer structure having controlled properties.

It should be noted that a so-called active elementary layer is a layer of material whereof the functional properties can be modified by ionic implantation. Said properties are preferably functional magnetic and/or electronic properties.

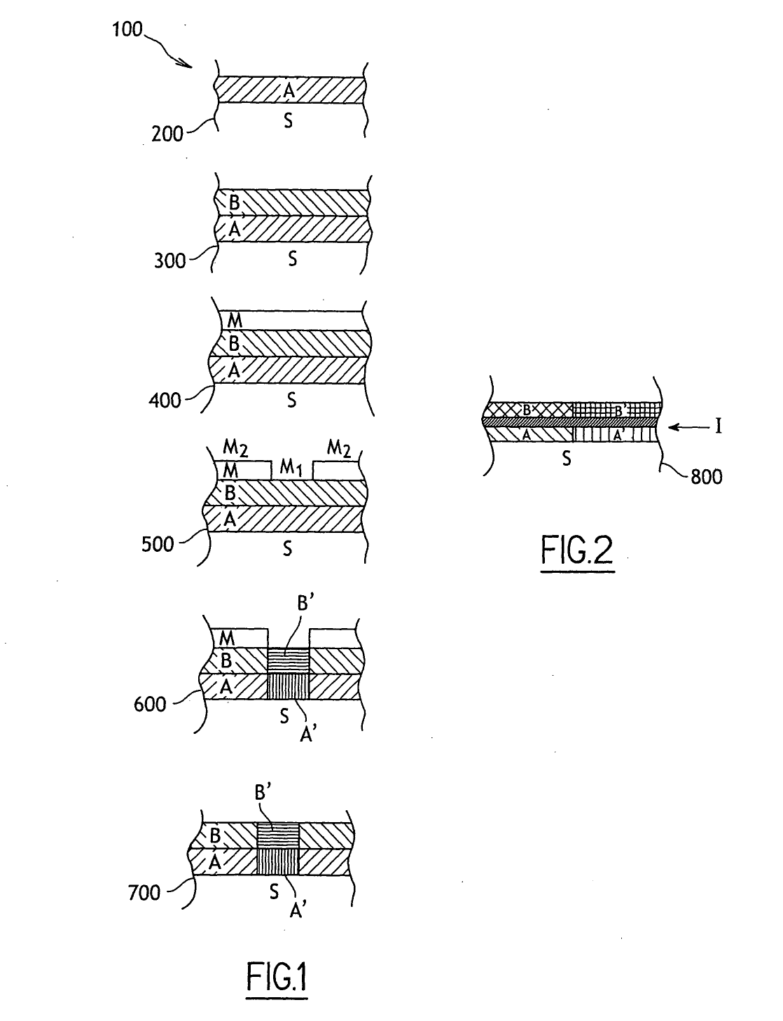

FIG. 1 illustrates the different manufacturing steps of a multilayer structure comprising two active elementary layers respectively of materials A and B. In a first step 200, the first active elementary layer A is deposited on a substrate S. In a second step 300, the second active elementary layer B is deposited on the active elementary layer A. In general, the steps of depositing layers are continued until at least the number n of active elementary layers of materials desired for manufacturing the multilayer structure is deposited.

Also, advantageously, the nth active elementary layer is a layer of material different to that of at least one of the preceding layers deposited. It is preferably a layer of material different to that of the preceding layer deposited. The reserve is deposited on the n layers deposited, in a third step 400. This reserve is preferably a photosensitive mask M.

This mask M can be a monolayer or multilayer mask. During step 500, insolation of the mask M is carried out. The mask M is then developed on the n deposited layers of the multilayer structure, that is, according to a certain pattern it will protect different zones M2 of the structure which it covers by also leaving other zones MI of the structure unprotected. Now that the mask M is developed, the implanting step of ionic elements 600 by way of the latter is carried out to modify the respective magnetic properties of the different active elementary layers A and B of the structure.

Throughout this step the unprotected zones MI of the layers see their properties functional modified, while the zones M2 protected by the mask M are not altered and correspond to the active elementary layers of materials A and B deposited initially. Advantageously, the implanting of ionic elements can be carried out either by means of bundles of ions, known implantation means which will not be detailed here, or directly by an ionic implantation technique via plasma immersion. The choice of the implantation technique of ionic elements to be used is a function of the ionic elements to be implanted, of the desired implantation depth or again of the necessity or not of a mass selection of ionic elements. For example, if low-energy ions are required for implantation, that is, ions having energy of less than 100 keV, the ionic implantation technique by plasma immersion will be preferred, whereas over and above 100 keV only traditional ionic implantation by bundle of ions will be conceivable.

With respect to the plasma immersion technique, this allows the implantation of ionic species by acceleration of positive ions of plasma by applying negative high-voltage pulses to the multilayer structure dipped in the plasma. The positive ions of the plasma are accelerated under the difference in potential applied between the plasma and the structure and will be implanted in the elementary layers of the latter. As the plasma completely encloses the structure, all zones MI not protected by the mask M can see their modified functional properties. Thus, the active elementary layers of materials A and B in the unprotected MI zones are altered to respectively give new layers of novel materials A′ and B′.

During step 600 of implantation of ionic species by plasma immersion the dose of ionic elements implanted at each level of active elementary layer of material deposited can also advantageously be selected precisely. In fact, the dose of ionic elements implanted can be modified as a function of the depth of implantation in the structure both by modulating the energy of the ions accelerated towards the structure and also by adjusting the effective duration of implantation of ions as a function of the depth of implantation.

It is also possible to modify the nature and/or the percentage of the species of ions implanted according to the depth of implantation in the multilayer structure. Controlled complex ionic implantation operations can advantageously be performed, simply using electric signals, in a single step 600 of ionic implantation on a multilayer structure. This permits easy automation and control in situ in real time of the ionic implantation method during manufacture of a multilayer structure having controlled properties according to the invention.

On completion of the ionic implantation step 600, the mask M is withdrawn (step 700), resulting in a structure having two active elementary layers having zones comprising the materials A and B and zones where their respective properties have been modified by formation, following implantation, of novel materials A′ and B′. Accordingly, the n active elementary layers of a fabricated multilayer structure according to the inventive method can be made from several materials having different magnetic properties and capable of leading to modifications of said properties before and after ionic implantation. Nickel can be cited as a non-limiting example, a ferromagnetic material which after implantation of nitrogen until formation of nickel nitride Ni₃N no longer constitutes ferromagnetic material. Manganese Mn is an antiferromagnetic material which becomes ferromagnetic (Mn₄N) after implantation of nitrogen.

A manufacturing method of a multilayer structure having controlled properties according to the invention advantageously enables a single implantation operation of ionic elements for the different active elementary layers. Repetition of fastidious elementary ionic implantation operations at each level of active elementary layer of a multilayer structure is avoided.

The manufacturing method of a structure with two layers having controlled properties illustrated in FIG. 1 required a series of seven elementary steps. If the multilayer structure comprises three layers of materials, eight elementary operations are carried out, or a depositing operation per supplementary layer and so on. In general, this method can comprise at a minimum a series of 5+n elementary steps. However, in a variant embodiment of a method according to the invention illustrated in FIG. 2, the depositing (step 800) of one or more so-called intermediate layers I between each couple of active elementary layers can also be provided without adding steps other than the depositing of these layers.

These intermediate layers I fulfil a function different to the elementary layers. In fact, they exhibit no particular functional magnetic properties. On the contrary, and preferably, they have specific electronic functional properties. They can be, for example, either conductive (metallic, semi-conductive or even supra-conductive) or insulating (dielectric).

During a manufacturing method of a multilayer structure according to the invention the depositing of these intermediate layers I is completed before the ionic implantation step 600. It is thus imperative to select the nature of the intermediate layers I such that they exhibit the required functional electronic properties after implantation, which can be similar or distinct in the protected zones M2 and non-protected zones MI by the mask M.

By way of non-limiting example, according to and composition of the initially deposited intermediate layer I, this can remain conductive or become insulating or inversely, after the implantation step of ionic elements 600 on the multilayer structure. Examples are aluminium, metal without magnetic properties which after implantation of nitrogen can constitute a very good dielectric, or titanium, molybdenum and tungsten which form nitrides and retain very good metallic conduction.

Also, other magnetic and electronic properties can be controlled during the manufacturing method of the multilayer structures. Properties such as the presence or not of magnetic properties, anisotropy, Curie or even Neel point, dielectric permitivity, the presence or not of optic gap or even the nature of the gap can thus be cited non-exclusively. By way of concrete and non-limiting illustration of a multilayer structure made by a method according to the invention an example is the easy manufacture of a structure elementary having two, three or even more levels of active magnetic elementary layers of nickel Ni and manganese Mn, by implanting of nitrogen. It is also possible to interpose insulating intermediate layers I of aluminium nitride or conductive of titanium nitride. For example, an elementary structure having two layers is made by successively depositing layers of nickel Ni and manganese Mn, each a few tens of nm, giving a value of the order of 30 nm.

On completion of the elementary operations of depositing, insolation and development of a mask, the latter has a pattern with openings on the surface of the multilayer structure, for example of the order of 100 nm and spaces of 100 nm. Nitrogen in the layers of nickel Ni and manganese Mn of a total thickness of 60 nm are then implanted by immersion in nitrogen plasma. The average implantation depths of the nitrogen ions N⁺ and N²⁺ present in the plasma in proportion 2/1 and accelerated at 30 keV are respectively 37 nm and 18 nm. Implantation of a total dose of ions of 2×10¹⁷ cm⁻² and removal of the mask M result in an elementary structure with layers of nickel Ni and manganese Mn in the zones protected by the mask M and layers Ni₃N and Mn₄N in the unprotected and implanted zones, lateral dispersion of the implantation remaining much less than the critical dimensions of the base pattern of the mask M.

A multilayer structure similar to the preceding but with an intermediate dielectric layer I of aluminium nitride AIN of a few nm, for example 5 nm, is obtained by depositing, after depositing of the layer of nickel Ni, a layer of AIN by reactive pulverisation of an aluminium target made of an argon/nitrogen plasma mixture. Ionic implantation of nitrogen is carried out as previously, but with ions of energy of 27 keV instead of 25 keV to respect the elementary thickness due to the layer aluminium nitride AIN. Following removal of the mask M this results in a structure having an intermediate layer of aluminium nitride AIN, whereof the dielectric character has not been modified by the implantation of nitrogen.

It should be noted that the two abovementioned examples are non-limiting and are given by way of illustration. It is understood that the present invention is not limited to the particular manufacturing methods which have been described, but extends to any variant in keeping with its basic idea. In particular, the present invention is not limited to the attached diagrams. The specific references illustrated in the preceding paragraphs are non-limiting examples of the invention.

1. A method for manufacturing a multilayer structure on a support, said structure comprising n active elementary layers of material, n being a whole number greater than or equal to two, comprising at least the following steps:
a depositing step of a first active elementary layer of material; and
a depositing step of an nth active elementary layer of material characterised in that it comprises a single step of implanting ionic species on the n active elementary layers of material deposited, via a reserve, for modifying respective properties of each of the n active elementary layers to obtain a multilayer structure having controlled properties.

2. The method according to claim 1, further comprising a depositing step of at least one layer of so-called intermediate material between two active elementary layers of material, which intermediate layer fulfils a function different to those of the active elementary layers, said step being performed prior to said implantation of ionic species on the n active elementary layers of material deposited, such that said implantation of ionic species is likely to also modify specific properties of said intermediate layer.

3. The method according to claim 1, wherein the nth active elementary layer is made of material different to that of at least one of the preceding deposited layers.

4. The method according to claim 3, wherein the nth active elementary layer is made of material different to that of the preceding deposited layer.

5. The method according to claim 1, further comprising a previous depositing step of the reserve on the n active elementary layers of material deposited followed by the steps of insolation and development of said reserve.

6. The method according to claim 1, wherein the reserve is a photosensitive monolayer or multilayer mask.

7. The method according to claim 1, wherein said implantation step of ionic species is performed by a plasma immersion technique.

8. The method according to claim 1, wherein said implantation step of ionic species is performed by means of a bundle of ions.

9. The method according to claim 1, wherein the controlled properties of the n active elementary layers of material and of the intermediate layers are magnetic and/or electronic properties.

10. The method according to claim 9, wherein the n active elementary layers of material have controlled magnetic and/or electronic properties and the intermediate layers have controlled electronic properties.

11. The method according to claim 1, wherein said implantation step of ionic species further comprises at least one sub-step for varying the dose of ionic species implanted as a function of the depth of implantation.

12. The method according to claim 1, wherein said implantation step of ionic species further comprises at least one sub-step for varying the nature and/or the percentage of ionic species as a function of implantation depth.
